(19) United States
(12) Patent Application Publication
(10) Pub. No.: US 2025/0098418 A1
(43) Pub. Date: Mar. 20, 2025

(54) DISPLAY DEVICE

(71) Applicant: Japan Display Inc., Tokyo (JP)

(72) Inventor: Tetsuo MORITA, Tokyo (JP)

(73) Assignee: Japan Display Inc., Tokyo (JP)

(21) Appl. No.: 18/884,171

(22) Filed: Sep. 13, 2024

(30) Foreign Application Priority Data
Sep. 14, 2023 (JP) 2023-149097

(51) Int. Cl. H10K 59/121; H10K 59/131; H10K 59/80

(52) U.S. Cl. CPC H10K 59/1213; H10K 59/131; H10K 59/871

(57) ABSTRACT

According to one embodiment, a display device includes a base, a plurality of first pixels disposed in a first area included in a display area on the substrate, and a plurality of second pixels disposed in a second area different from the first area, included in the display area on the substrate. Each of the plurality of first pixels includes a first pixel circuit including a plurality of transistors and a first display element driven by the first pixel circuit. Each of the plurality of second pixels includes a second pixel circuit including a plurality of transistors and a second display element driven by the second pixel circuit. The transistors in the second pixel circuit are less in number than the transistors in the first pixel circuit.

### CROSS-REFERENCE TO RELATED APPLICATION

This application is based upon and claims the benefit of priority from Japanese Patent Application No. 2023-149097, filed Sep. 14, 2023, the entire contents of which are incorporated herein by reference.

### FIELD

Embodiments described herein relate generally to a display device.

### BACKGROUND

In recent years, display devices in which organic light emitting diodes (OLEDs) are applied as display elements have been put to practical use, and it is known that, for example, electronic devices such as smartphones are equipped with such display devices.

In such electronic devices, by adopting a configuration in which a camera is placed on a rear side of the display device (display area), the display area can be expanded to the area overlapping the camera.

But, in the case of such a configuration, light must enter the camera (the image pickup element of the camera) via the display device, and therefore it is necessary to ensure sufficient light transmittance in the display device (the region of the display area that is overlapping the camera).

### BRIEF DESCRIPTION OF THE DRAWINGS

FIG. 1 is a diagram showing a configuration example of a display device according to an embodiment.

FIG. 2 is a diagram showing an example of a layout of a plurality of subpixels contained in a pixel.

FIG. 3 is a diagram showing another example of the layout of the plurality of subpixels contained in the pixel.

FIG. 4 is a cross-sectional view schematically showing the display device taken along line A-A in FIG. 2.

FIG. 5 is an enlarged cross-sectional view schematically showing a partition.

FIG. 6 is a cross-sectional view schematically showing display elements formed by using the partition.

FIG. 7 is a cross-sectional view schematically illustrating display elements formed by using the partition.

FIG. 8 is a cross-sectional view schematically illustrating display elements formed by using the partition.

FIG. 9 is a plan view showing a part of an electronic device in which a display device is incorporated.

FIG. 10 is a diagram illustrating pixel circuits disposed in a first display area.

FIG. 11 is a diagram illustrating pixel circuits disposed in a second display area.

FIG. 12 is a cross-sectional view schematically showing the display device taken along line B-B in FIG. 11.

FIG. 13 is a diagram illustrating an example of a circuit configuration of the pixel circuits disposed in the first display area.

FIG. 14 is a diagram illustrating another example of a circuit configuration of the pixel circuits disposed in the second display area.

FIG. 15 is a diagram schematically showing arrangement of various wiring lines connected to the pixel circuits shown in FIGS. 13 and 14.

FIG. 16 is a diagram illustrating an operation of the pixel circuit shown in FIG. 13.

FIG. 17 is a diagram illustrating an operation of the pixel circuit shown in FIG. 14.

FIG. 18 is a diagram illustrating still another example of a circuit configuration of the pixel circuits disposed in the first display area.

FIG. 19 is a diagram illustrating still another example of a circuit configuration of the pixel circuits disposed in the second display area.

FIG. 20 is a diagram schematically showing arrangement of various wiring lines connected to the pixel circuits shown in FIGS. 18 and 19.

FIG. 21 is a diagram illustrating an operation of the pixel circuit shown in FIG. 18.

FIG. 22 is a diagram illustrating an operation of the pixel circuit shown in FIG. 19.

### DETAILED DESCRIPTION

In general, according to one embodiment, a display device includes a base, a plurality of first pixels disposed in a first area included in a display area on the substrate, and a plurality of second pixels disposed in a second area different from the first area, included in the display area on the substrate. Each of the plurality of first pixels includes a first pixel circuit including a plurality of transistors and a first display element driven by the first pixel circuit. Each of the plurality of second pixels includes a second pixel circuit including a plurality of transistors and a second display element driven by the second pixel circuit. The transistors in the second pixel circuit are less in number than the transistors in the first pixel circuit.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that in the drawings, X, Y, and Z axes, which are orthogonal to each other, are noted for ease of understanding as necessary. The direction along the X axis is referred to as a first direction X, the direction along the Y axis as a second direction Y, and the direction along the Z axis as a third direction Z. Viewing various elements parallel to the third direction Z is referred to as plan view.

A display device of this embodiment is an organic electroluminescent display device equipped with organic light emitting diodes (OLEDs) as display elements, and can be mounted, for example, in an electronic device such as a smart phone. Note that the electronic device in which the display device of this embodiment is to be mounted may be electronic devices other than a smartphone (for example, tablet terminals or the like).

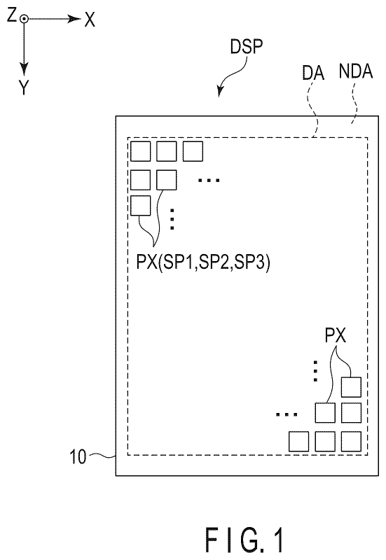

FIG. 1 is a diagram showing a configuration example of a display device DSP according to this embodiment. The display device DSP includes a display area DA on which images are displayed and a non-display area NDA located around the display area DA on an insulating base 10. The base 10 may be glass or a flexible resin film.

In this embodiment, the shape of the base 10 in plan view is rectangular. But, the shape of the base 10 in plan view is not limited to rectangular, but may be some other shape such as a square, circle or oval.

The display area DA includes a plurality of pixels PX disposed (arranged) in a matrix along the first direction X and the second direction Y. The pixels PX each include a plurality of subpixels SP. For example, the subpixels SP include red subpixels SP1, green subpixels SP2, and blue subpixels SP3. Note that the subpixels SP may include subpixels of some other color such as white together with the subpixels SP1, SP2 and SP3. The plurality of subpixels SP may as well include subpixels of some other color in place of any of the subpixels SP1, SP2 and SP3.

Note that each of the plurality of subpixels SP includes a pixel circuit and a display element driven by the pixel circuit, as will be described later in detail. The pixel circuit is constituted by, for example, a plurality of transistors (switching elements respectively constituted by thin-film transistors). The display element is an organic light emitting diode as a light emitting element. For example, the subpixels SP1 each include a display element which emits light in a red wavelength range, the subpixels SP2 each include a display element which emit light in a green wavelength range, and the subpixels SP3 each include a display element which emits light in a blue wavelength range.

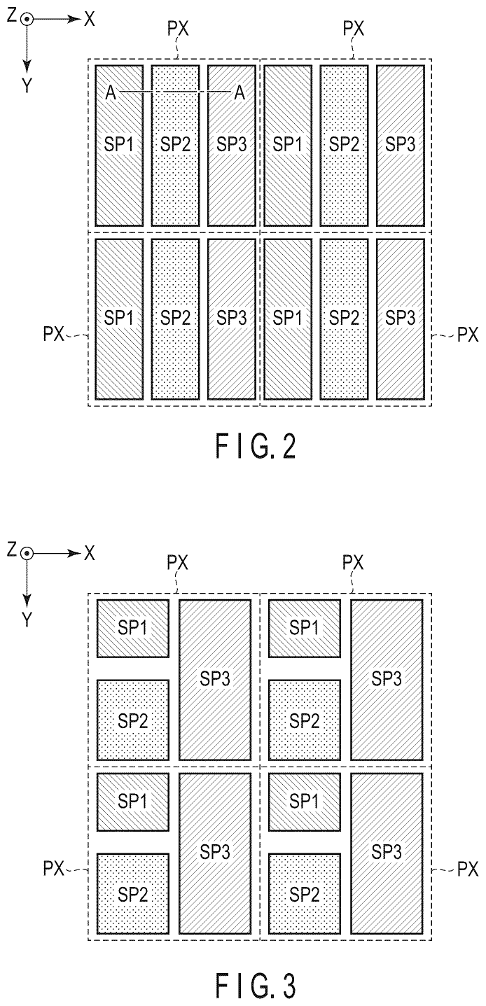

FIG. 2 shows an example of layout of the plurality of subpixels SP (SP1, SP2 and SP3) contained in pixels PX. Here, four pixels PX will be focused for explanation.

The subpixels SP1, SP2 and SP3, which constitute one pixel PX, are formed on a shape of approximately a rectangle elongated along the second direction Y and arranged along the first direction X. As two pixels PX arranged along the first direction X are focused, the colors displayed at adjacent subpixels SP are different from each other. Further, when focusing on two pixels PX arranged along the second direction Y, the colors displayed at adjacent subpixels SP are the same. Note that the areas of the subpixels SP1, SP2, and SP3 may be the same as or different from each other.

FIG. 3 shows another example of the layout of a plurality of subpixels SP (SP1, SP2 and SP3) contained in pixels PX.

The subpixels SP1 and SP2, which constitute one pixel PX, are arranged along the second direction Y, the subpixels SP1 and SP3 are arranged along the first direction X, and the subpixels SP2 and SP3 are arranged along the first direction X. The subpixels SP1 are each formed into approximately a rectangular shape elongated along the first direction X, and the subpixels SP2 and SP3 are each formed into approximately a rectangular shape elongated along in the second direction Y. The area of the subpixels SP2 is larger than that of the subpixels SP1, and the area of the subpixels SP3 is larger than that of the subpixel SP2. Note that the area of the subpixel SP1 may be the same as that of the subpixel SP2.

As two pixels PX arranged along the first direction X are focused, in the region where the subpixels SP1 and SP3 are arranged alternately and in the region where the subpixels SP2 and SP3 are arranged alternately, the colors displayed in the subpixels SP adjacent to each other along the first direction X are different from each other. On the other hand, focusing on two pixels PX arranged along the second direction Y, in the region where the subpixels SP1 and SP2 are arranged alternately, the colors displayed in subpixels SP adjacent to each other in the second direction Y are different from each other. Further, in the region where a plurality of subpixels SP3 are arranged in a row, the colors displayed in the subpixels SP adjacent to each other in the second direction are the same as each other.

Note that the outlines of the subpixels SP1, SP2 and SP3 shown in FIGS. 2 and 3 correspond to the outlines of the areas where colors are displayed in the subpixels SP (that is, the light emission areas), but here they are represented in a simplified way and do not necessarily reflect the actual shapes.

Here, a rib and a partition are arranged in the display area DA in this embodiment, as will be described in detail later. The rib includes apertures in the subpixels SP1, SP2 and SP3, respectively. The partition is placed at a boundary between each adjacent pair of subpixels SP so as to overlap the rib in plan view. More specifically, the partition is placed between each pair of apertures (subpixels SP) adjacent to each other along the first direction X and between each pair of apertures (subpixels SP) adjacent to each other along the second direction Y. With this configuration, the partition has a lattice shape formed as a whole to compartmentalize the subpixels SP1, SP2 and SP3 from each other. In other words, it can be said that the partition has apertures in the subpixels SP1, SP2, and SP3 respectively as in the case of the rib.

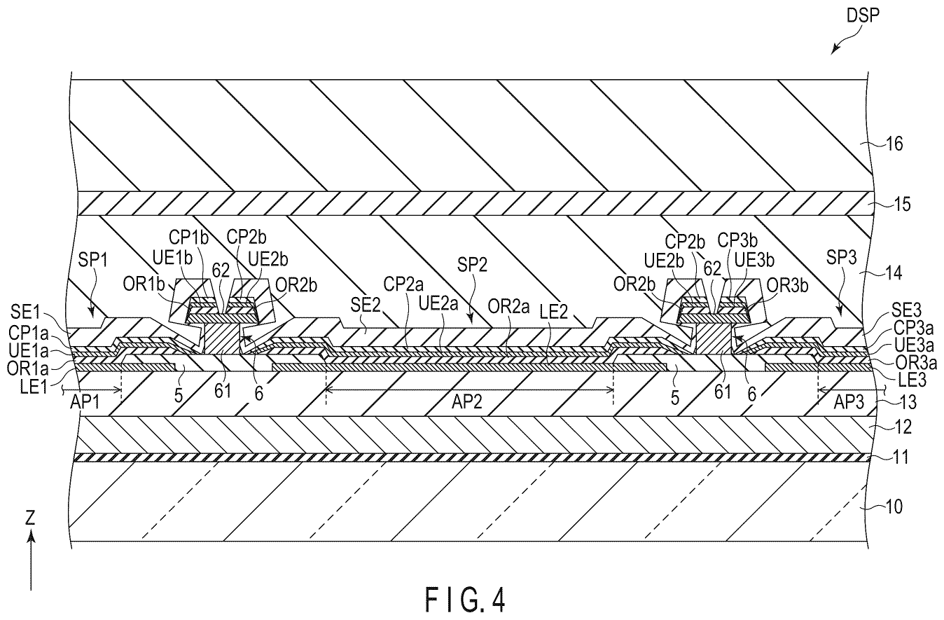

FIG. 4 is a cross-sectional view schematically showing the display device DSP taken along line A-A in FIG. 2. In the display device DSP, an insulating layer 11, referred to as an undercoat layer, is disposed on a base 10 having light transmissivity such as the glass described above (on the surface on a side where the display element or the like is disposed).

The insulating layer 11 has a three-layer stacked structure including, for example, a silicon oxide film (SiO), a silicon nitride film (SiN), and a silicon oxide film (SiO). Note that the insulating layer 11 is not limited to a three-layer stacked structure. The insulating layer 11 may have a stacked structure with more than three layers, or may have a single-layer structure or a two-layer stacked structure.

On the insulating layer 11, a circuit layer 12 is disposed. The circuit layer 12 includes pixel circuits (various circuits and wiring lines) that drive the display element contained in each of the subpixels SP1, SP2, and SP3 as described above. The circuit layer 12 is covered by an insulating layer 13.

The insulating layer 13 functions as a planarization film that planarizes the unevenness caused by the circuit layer 12. Although not shown in FIG. 4, the insulating layer 13 has contact holes provided therein for connecting lower electrodes LE to the pixel circuits.

The lower electrodes LE (LE1, LE2 and LE3) are located on the insulating layer 13. The rib 5 is disposed on the insulating layer 13 and the lower electrodes LE. End portions (a part thereof) of the lower electrodes LE are covered by the rib 5.

The partition 6 includes a lower portion 61 disposed above the rib 5 and an upper portion 62 which covers the upper surface of the lower portion 61. The upper portion 62 has a width greater than that of the lower portion 61 along the first direction X and the second direction Y. With this structure, the partition 6 has such a shape that both end portions of the upper portion 62 protrude beyond the side surfaces of the lower portion 61, respectively. The shape of the partition 6 with such a state can be referred to as an overhang shape.

The organic layers OR (OR1, OR2, and OR3) and the upper electrodes UE (UE1, UE2 and UE3), together with the lower electrodes LE (LE1, LE2 and LE3) described above, constitute a display element provided in the subpixel SP.

As shown in FIG. 4, the organic layer OR1 includes a first organic layer OR1a and a second organic layer OR1b spaced apart from each other. The upper electrode UE1 includes a first upper electrode UE1a and a second upper electrode UE1b spaced apart from each other. The first organic layer OR1a is in contact with the lower electrode LE1 via the aperture AP1 (an aperture of the rib 5 in the subpixel SP1) and further covers a part of the rib 5. The second organic layer OR1b is located above the upper portion 62. The first upper electrode UE1a is disposed to oppose the lower electrode LE1 and cover the first organic layer OR1a. Further, the first upper electrode UE1a is in contact with the side surface of the lower portion 61. The second upper electrode UE1b is located above the partition 6 and covers the second organic layer OR1b.

Further, as shown in FIG. 4, the organic layer OR2 includes a first organic layer OR2a and a second organic layer OR2b spaced apart from each other. The upper electrode UE2 includes a first upper electrode UE2a and a second upper electrode UE2b spaced apart from each other. The first organic layer OR2a is in contact with the lower electrode LE2 via the aperture AP2 (an aperture of the rib 5 in the subpixel SP2) and also covers a part of the rib 5. The second organic layer OR2b is located above the upper portion 62. The first upper electrode UE2a is disposed to oppose the lower electrode LE2 and cover the first organic layer OR2a. Further, the first upper electrode UE2a is in contact with the side surface of the lower portion 61. The second upper electrode UE2b is located above the partition 6 and covers the second organic layer OR2b.

Further, as shown in FIG. 4, the organic layer OR3 includes a first organic layer OR3a and a second organic layer OR3b separated from each other. The upper electrode UE3 includes a first upper electrode UE3a and a second upper electrode UE3b spaced apart from each other. The first organic layer OR3a is in contact with the lower electrode LE3 via the aperture AP3 (an aperture of the rib 5 in the subpixel SP3) and also covers a part of the rib 5. The second organic layer OR3b is located above the upper portion 62. The first upper electrode UE3a is disposed to oppose the lower electrode LE3 and cover the first organic layer OR3a. Further, the first upper electrode UE3a is in contact with the side surface of the lower portion 61. The second upper electrode UE3b is located above the partition 6 and covers the second organic layer OR3b.

In the example shown in FIG. 4, the subpixels SP1, SP2, and SP3 include cap layers CP1, CP2, and CP3 (optical path adjustment layers), respectively, for adjusting the optical properties of the light emitted by the light emitting layers of the organic layers OR1, OR2, and OR3.

The cap layer CP1 includes a first cap layer CP1a and a second cap layer CP1b spaced apart from each other. The first cap layer CP1a is located in the aperture AP1 and disposed on the first upper electrode UE1a. The second cap layer CP1b is located above the partition 6 and disposed on the second upper electrode UE1b.

The cap layer CP2 includes a first cap layer CP2a and a second cap layer CP2b spaced apart from each other. The first cap layer CP2a is located in the aperture AP2 and disposed on the first upper electrode UE2a. The second cap layer CP2b is located above the partition 6 and disposed on the second upper electrode UE2b.

The cap layer CP3 includes a first cap layer CP3a and a second cap layer CP3b spaced apart from each other. The first cap layer CP3a is located in the aperture AP3 and disposed on the first upper electrode UE3a. The second cap layer CP3b is located above the partition 6 and disposed on the second upper electrode UE3b.

Sealing layers SE1, SE2, and SE3 are disposed on the subpixels SP1, SP2 and SP3, respectively. The encapsulating layer SE1 continuously covers each of the components of the subpixel SP1 including the first cap layer CP1a, the partition 6 and the second cap layer CP1b. The sealing layer SE2 continuously covers each of the components of the subpixel SP2 including the first cap layer CP2a, the partition 6 and the second cap layer CP2b. The sealing layer SE3 continuously covers each of the components of the subpixel SP3 including the first cap layer CP3a, the partition 6 and the second cap layer CP3b.

In the example shown in FIG. 4, the second organic layer OR1b, the second upper electrode UE1b, the second cap layer CP1b and the sealing layer SE1 on the partition 6 between the subpixels SP1 and SP2 are spaced apart from the second organic layer OR2b, the second upper electrode UE2b, the second cap layer CP2b and the sealing layer SE2 on the partition 6, respectively. Further, the second organic layer OR2b, the second upper electrode UE2b, the second cap layer CP2b and the sealing layer SE2 on the partition 6 between the subpixels SP2 and SP3 are spaced apart from the second organic layer OR3b, the second upper electrode UE3b, the second cap layer CP3b and the sealing layer SE3 on the partition 6, respectively.

The sealing layers SE1, SE2 and SE3 are covered by a resin layer 14 (planarization film). The resin layer 14 is covered by a sealing layer 15. Further, the sealing layer 15 is covered by a resin layer 16.

The insulating layer 13 and the resin layers 14 and 16 are each formed of an organic material. The rib 5, the sealing layers 15 and SE (SE1, SE2, and SE3) are each formed, for example, of an inorganic material such as silicon nitride (SiNx).

The lower portion 61 of the partition 6 has conductivity. The upper portion 62 of the partition 6 may have conductivity, similarly. The lower electrode LE may be formed of a transparent conductive oxide such as indium tin oxide (ITO) or may have a stacked structure of a metal material such as silver (Ag) and a conductive oxide. The upper electrode UE may be formed of a conductive oxide such as ITO.

When the potential of the lower electrode LE is relatively higher than that of the upper electrode UE, the lower electrode LE corresponds to an anode and the upper electrode UE corresponds to a cathode. When the potential of the upper electrode UE is relatively higher than that of the lower electrode LE, the upper electrode UE corresponds to an anode and the lower electrode LE corresponds to a cathode.

The organic layer OR includes a pair of functional layers and a light emitting layer disposed between these functional layers. As an example, the organic layer OR has a configuration in which a hole injection layer, a hole import layer, an electron blocking layer, an emission layer, a hole blocking layer, an electron transport layer and an electron injection layer are stacked in order.

The cap layers CP (CP1, CP2, and CP3) are formed, for example, by a multilayer of a plurality of transparent thin films. The multilayer may include, as a plurality of thin films, thin films formed of inorganic materials and thin films formed of organic materials. The plurality of thin films have refractive indices different from each other. The material of the thin films constituting the multilayer is different from the material of the upper electrode UE and further different from the material of the sealing layer SE. Note that the cap layers CP may be omitted.

A common voltage is supplied to the partition 6. The common voltage is supplied to the upper electrodes UE (the first upper electrodes UE1a, UE2a and UE3a), which are brought into contact with the side surfaces of the lower portion 61, respectively. To the lower electrodes LE (LE1, LE2 and LE3), a pixel voltage is supplied via the pixel circuits of the subpixels SP (SP1, SP2, and SP3), respectively.

When a potential difference is created between the lower electrode LE1 and the upper electrode UE1, the light emitting layer of the first organic layer OR1a emits light in the red wavelength range. When a potential difference is created between the lower electrode LE2 and the upper electrode UE2, the light emitting layer of the first organic layer OR2a emits light in the green wavelength range. When a potential difference is created between the lower electrode LE3 and the upper electrode UE3, the light emitting layer of the first organic layer OR3a emits light in the blue wavelength range.

As another example, the light emitting layers of the organic layers OR1, OR2, and OR3 may emit light of the same color (for example, white). In this case, the display device DSP may include color filters which convert the light emitted by the light emitting layers into light of a color corresponding to the respective one of the subpixels SP1, SP2, and SP3. The display device DSP may as well include layers containing quantum dots that are excited by the light emitted by the light emitting layers to generate light of a color corresponding to the respective one of the subpixels SP1, SP2, and SP3.

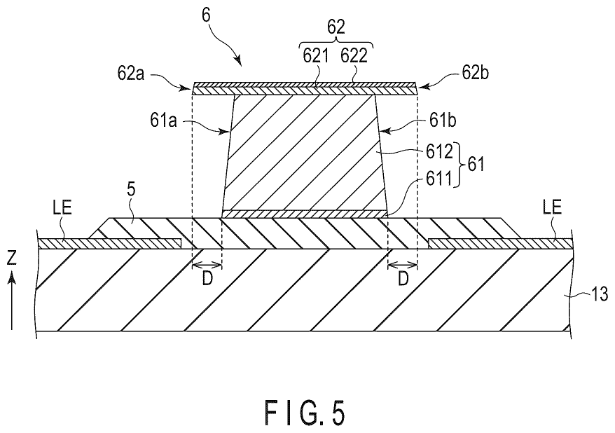

FIG. 5 is an enlarged cross-sectional view schematically showing the partition 6. In the illustration of FIG. 5, elements other than the rib 5, the partition 6, the insulating layer 13 and a pair of lower electrodes LE are omitted. The pair of lower electrodes LE correspond any ones of the lower electrodes LE1, LE2, and LE3 described above.

In the example shown in FIG. 5, the lower portion 61 of the partition 6 includes a barrier layer (bottom portion) 611 disposed on the rib 5 and a metal layer (axial portion) 612 disposed on the barrier layer 611. The barrier layer 611 is formed of a material different from that of the metal layer 612, for example, a metal material such as molybdenum (Mo), titanium (Ti), titanium nitride (TiN) or the like. The metal layer 612 is formed thicker than the barrier layer 611. The metal layer 612 may be of a single layer structure or a stacked structure of different metal materials. As an example, the metal layer 612 is formed of aluminum (Al), for example.

The upper portion (top portion) 62 is thinner than the lower portion 61. In the example shown in FIG. 5, the upper portion 62 includes a first layer 621 disposed on the metal layer 612 and a second layer 622 disposed on the first layer 621. As one example, the first layer 621 is formed of titanium (Ti), for example, and the second layer 622 is formed of ITO, for example.

In the example shown in FIG. 5, the width of the lower portion 61 decreases as the location approaches the upper portion 62. That is, the side surfaces 61a and 61b of the lower portion 61 are inclined with respect to the third direction Z. Note that the upper portion 62 includes an end portion 62a protruding from the side surface 61a and an end portion 62b protruding from the side surface 61b.

The amount of protrusion D of the end portions 62a and 62b from the side surfaces 61a and 61b (hereinafter referred to as the protrusion amount D of the partition 6) is, for example, 2.0 μm or less. The protrusion amount D of the partition 6 in this embodiment corresponds to the distance between the lower end (the barrier layer 611) of the side surfaces 61a and 61b and the end portions 62a and 62b in the width direction (the first direction X or second direction Y) orthogonal to the third direction Z of the partition 6.

Note that in the example shown in FIG. 5, the side surface of the barrier layer 611 and the side surface of the metal layer 612 are aligned with each other to form a plane without steps, but, for example, the side surface of the barrier layer 611 may be slightly set back with respect to the side surface of the metal layer 612 or may protrude with respect to the side surface of the metal layer 612. Further, in FIG. 5, the barrier layer 611 and the side surfaces of the metal layer 612 (that is, the side surfaces 61a and 61b of the lower portion 61) are inclined with respect to the third direction Z, but the side surfaces may be parallel to the third direction Z.

The structure of the partition 6 and the material of each part of the partition 6 may be selected as appropriate, taking into consideration, for example, the technique of forming the partition 6.

Here, in this embodiment, the partition 6 is formed to compartmentalize the subpixels SP in plan view. The organic layer OR described above is formed, for example, by an anisotropic or directional vacuum evaporation method. Here, note that when the organic material for forming the organic layer OR is evaporated over the entire base 10 with the partition 6 in place, the organic layer OR is no substantially formed on the side surfaces of the partition 6 because the partition 6 has such a shape as shown in FIGS. 4 and 5. With this configuration, such an organic layer OR (display element) can be formed that it is divided into each subpixel SP by the partition 6.

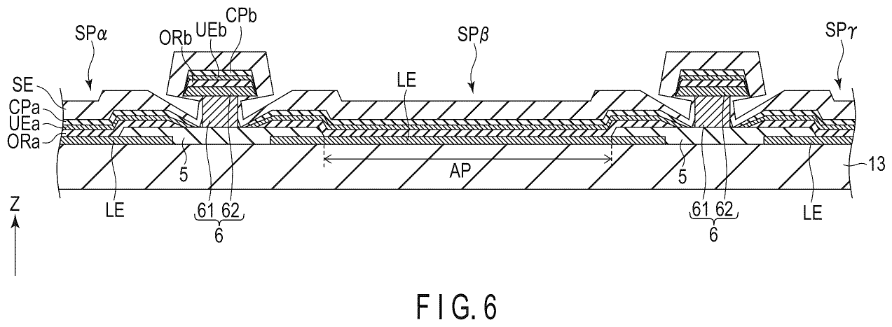

FIGS. 6 to 8 are schematic cross-sectional views for explaining the display element formed by using the partition 6. Note that in FIGS. 6 to 8, the base 10, the insulating layer 11 and the circuit layer 12 are omitted. Further the subpixels SPa, SPB and SPY shown in FIGS. 6 to 8 correspond to the subpixels SP1, SP2, and SP3, in any combinations.

First, the organic layer OR, the upper electrode UE, the cap layer CP, and the sealing layer SE are formed by vapor deposition in order on the entire base 10 as shown in FIG. 6 with the partition 6 arranged as described above. The organic layer OR includes a light emitting layer that emits light of a color corresponding to that of the subpixel SPa. By the overhanging partition 6, the organic layer OR is divided into a first organic layer ORa in contact with the lower electrode LE via the aperture AP and a second organic layer ORb on the partition 6, the upper electrode UE is divided into a first upper electrode UEa covering the first organic layer ORa and a second upper electrode UEb covering the second organic layer ORb, and the cap layer CP is divided into a first cap layer CPa covering the first upper electrode UEa and a second cap layer CPb covering the second upper electrode UEb. The first upper electrode UEa is in contact with the lower portion 61 of the partition 6. The sealing layer SE continuously covers the first cap layer CPa, the second cap layer CPb and the partition 6.

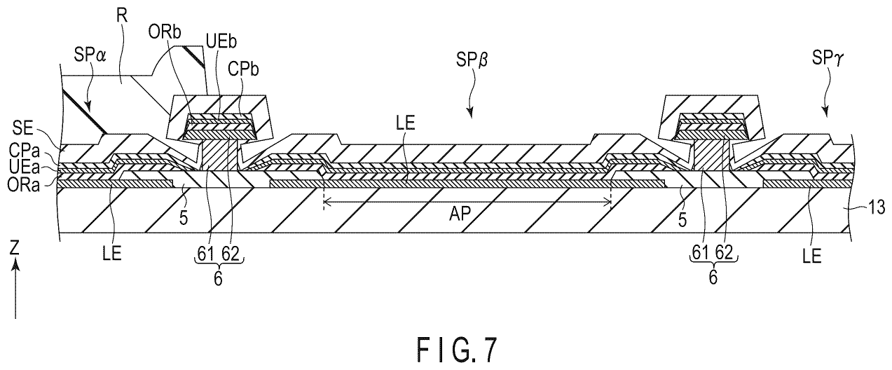

Next, as shown in FIG. 7, the resist R is formed on the sealing layer SE. The resist R covers the subpixel SPa. That is, the resist R is disposed directly above the first organic layer ORa, the first upper electrode UEa, and the first cap layer CPa, which are located in the subpixel SPx. The resist R is further located directly above the portion of the second organic layer ORb, the second upper electrode UEb and the second cap layer CPb on the partition 6 between the subpixel SPa and the subpixel SPB, which is closer to the subpixel SPa. That is, at least a part of the partition 6 is exposed from the resist R.

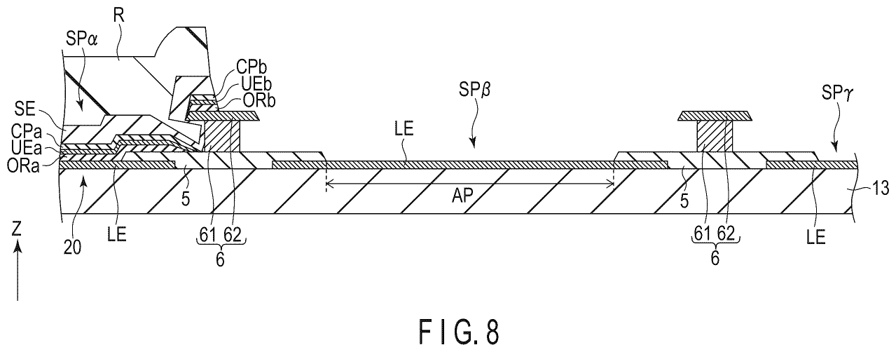

Further, by etching using the resist R as a mask, portions of the organic layer OR, the upper electrode UE, the cap layer CP and the sealing layer SE, which are exposed from the resist R are removed as shown in FIG. 8. With this configuration, such a display element containing the lower electrode LE, the first organic layer ORa, the first upper electrode UEa and the first cap layer CPa is formed in the subpixel SPa. On the other hand, in the subpixels SPB and SPY, the lower electrode LE is exposed. Note that the etching described above includes, for example, dry etching of the sealing layer SE, wet etching and dry etching of the cap layer CP, wet etching of the upper electrode UE, and dry etching of the organic layer OR.

After the display element of the subpixel SPa is formed as described above, the resist R is removed and the display elements of the subpixels SPB and SPY are formed in order as in the case of the subpixel SPa.

As explained for the subpixels SPa, SPB and SPY in the example provided above, by forming the display elements of the subpixels SP1, SP2, and SP3 and further the forming resin layer 14, the sealing layer 15 and the resin layer 16, the configuration of the display device DSP shown in FIG. 4 is realized.

Here, it is assumed that the display device DSP of this embodiment is built in an electronic device such as a smartphone together with a camera, for example, for use.

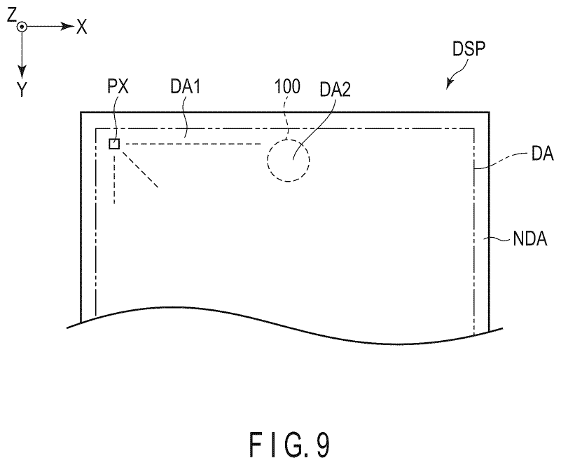

FIG. 9 is a plan view showing a part of an electronic device in which the display device DSP (display panel) of this embodiment is incorporated. As described above, in the display device DSP, the display area DA includes a plurality of pixels PX (subpixels SP1, SP2, and SP3) arranged in a matrix along the first direction X and second direction Y. Further, the display device DSP includes a display surface having a display area DA and a rear surface opposing the display surface (hereinafter referred to as the rear surface of the display device DSP). In an electronic device in which the display device DSP of this embodiment is incorporated, it is assumed that a camera 100 for capturing images, for example, is arranged on the rear surface side of the display device DSP.

In this case, as shown in FIG. 9, in order to expand the display area DA in the electronic device (display device DSP) (to expand the range of the display area DA), it is considered that the camera 100 is placed in a position which overlaps the display area DA (that is, a plurality of pixels PX).

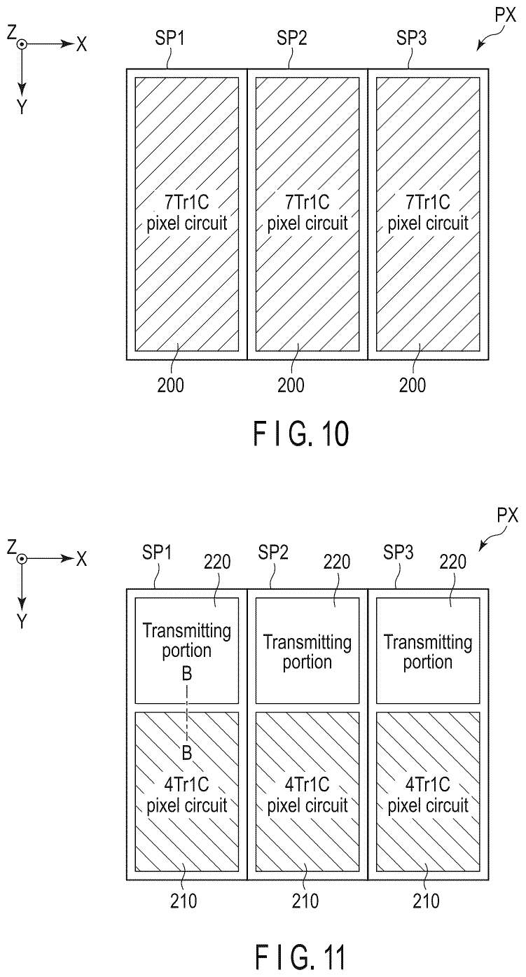

Here, the subpixels SP (SP1, SP2 and SP3) disposed in the display area DA each include a pixel circuit that drives the display element, and here it is assumed that the pixel circuit is, for example, a 7Tr1C pixel circuit is constituted by, for example, seven transistors (Tr) and one storage capacitor (C). In this case, as shown in FIG. 10, the pixel circuit 200 is arranged in the area occupying most of the subpixels SP1, SP2 and SP3 in plan view, and the light transmittance in the area overlapping the camera 100 (that is, the area including pixels PX) may be reduced due to the effect of the pixel circuit 200. As a result, sufficient light may not enter (the image sensor of) the camera 100 via the display device DSP.

In this case, for example, a configuration in which pixels PX is thinned out in the area overlapping the camera 100 can be considered. But, according to a configuration in which pixels PX are simply thinned out, the resolution of the area overlapping the camera 100 may decrease, and the display quality of the display device DSP may degrade.

Therefore, in this embodiment, the pixel circuit 200 (7Tr1C pixel circuit) shown in FIG. 10 is disposed in an area DA1 of the display area DA which does not overlap the camera 100 (hereinafter referred to as a first display area DA1) to drive the display element. On the other hand, in an area DA2 (hereinafter referred to as a second display area DA2), a pixel circuit 210 (4Tr1C pixel circuit) constituted by, for example, four transistors and one storage capacitor is disposed to drive the display element, as shown in FIG. 11.

In the case of such a configuration, the pixel circuit 210 (4Tr1C pixel circuit) disposed in the second display area DA2 is simplified more than the pixel circuit 200 (7Tr1C pixel circuit) disposed in the first display area DA1, and therefore as shown in FIG. 11, the area of the region of the second display area DA2, which is occupied by the pixel circuit 210 can be made smaller, and a transmitting portion 220 corresponding to the area with high light transmittance can be placed.

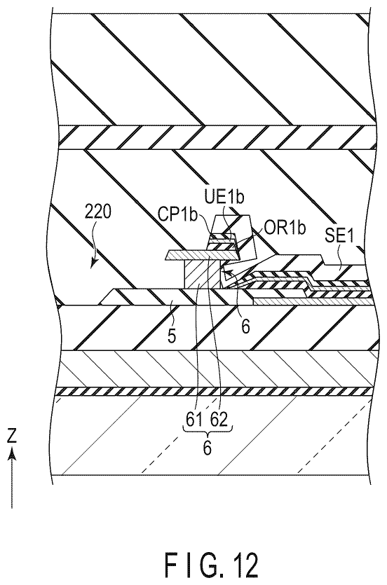

FIG. 12 is a cross-sectional view schematically showing the display device DSP taken along line B-B in FIG. 11. As shown in FIG. 12, the display elements (the lower electrode LE1, organic layer OR1 and upper electrode UE1), the cap layer CP1 and the sealing layer SE1 are disposed in the area overlapping the pixel circuit 210 (the area overlapping the aperture of the rib 5), whereas in the transmitting portion 220, the display element, the cap layer and the sealing layer are not disposed in the area overlapping the apertures of the rib 5. Further, in FIG. 12, the circuit layer 12 is disposed in a position overlapping the transmitting portion 220, and here note that in the circuit layer 12, for example, a wiring line connected to the respective subpixel SP located in the vicinity of the transmitting portion 220 may be disposed, whereas the pixel circuit 210 is not disposed.

Further, in the second display area DA2, it is assumed that the area overlapping the pixel circuit 210 and the transmitting portion 220 are compartmentalized by the rib 5 and the partition 6 as in the case of the subpixels SP.

According to the transmitting portion area 220 of such a configuration, it is possible to achieve high light transmittance without the influence of display elements or the like.

The pixel circuit 200 arranged in the first display area DA1 and the pixel circuit 210 arranged in the second display area DA2 in this embodiment will now be described.

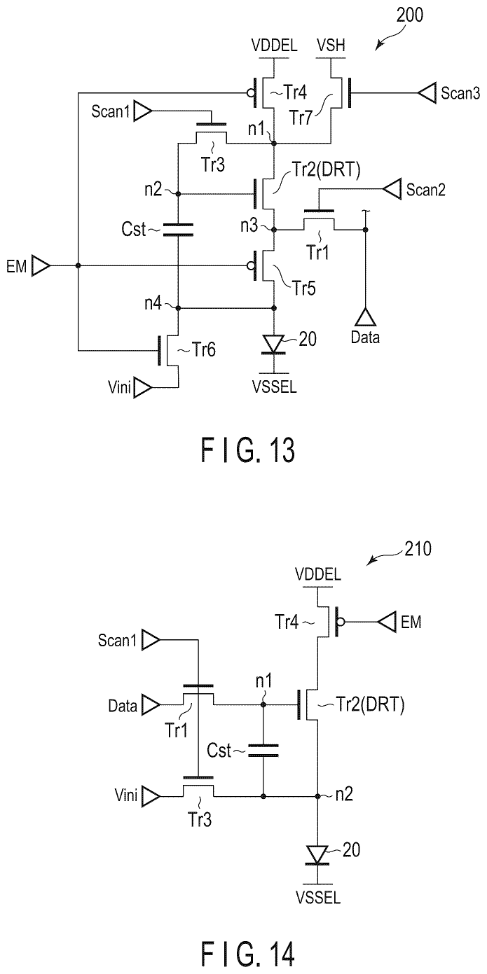

FIG. 13 shows an example of the circuit configuration of the pixel circuit 200 to be placed in the first display area DA1. As shown in FIG. 13, the pixel circuit 200 is a 7Tr1C pixel circuit constituted by seven transistors (hereinafter referred to as the first through seventh transistors) Tr1 to Tr7 and one storage capacitor Cst.

In the following description, one of the source and drain terminals of each of the first to seventh transistors Tr1 to Tr7 shown in FIG. 13 is referred to as a first terminal and the other as the second terminal. Further, one of the terminals of the storage capacitor Cst (realized by the capacitive element) shown in FIG. 13 is referred to as a first terminal and the other terminal as a second terminal.

The first terminal of the first transistor Tr1 is connected to the first terminal of the second transistor Tr2 and the second terminal of the fifth transistor Tr5 via a node n3. The second terminal of the first transistor Tr1 is connected to a data signal line which supplies a data signal Data. The data signal Data corresponds to the signal (pixel signal) to be written to the pixel. Note that the first transistor Tr1 is, for example, an n-channel transistor.

The second transistor Tr2 corresponds to a drive transistor (DRT) that supplies a current to the display element 20 contained in the subpixel SP (that is, the display element 20 driven by the pixel circuit 200). The first terminal of the second transistor Tr2 is connected to the first terminal of the first transistor Tr1 and the second terminal of the fifth transistor Tr5 via a node n3. The second terminal of the second transistor Tr2 is connected to the second terminal of the third transistor Tr3, the first terminal of the fourth transistor Tr4 and the first terminal of the seventh transistor Tr7 via a node n1. Note that the second transistor Tr2 is, for example, an n-channel transistor.

The first terminal of the third transistor Tr3 is connected to the gate terminal of the second transistor Tr2 and the second terminal of the storage capacitor Cst via a node n2. The second terminal of the third transistor Tr3 is connected to the second terminal of the second transistor Tr2, the first terminal of the fourth transistor Tr4 and the first terminal of the seventh transistor Tr7 via a node n1. Note that the third transistor Tr3 is, for example, an n-channel transistor.

The first terminal of the fourth transistor Tr4 is connected to the second terminal of the second transistor Tr2, the second terminal of the third transistor Tr3 and the first terminal of the seventh transistor Tr7 via the node n1. The second terminal of the fourth transistor Tr4 is connected to a power line for supplying a power supply voltage VDDEL. Note that the fourth transistor Tr4 is, for example, a p-channel transistor.

The first terminal of the fifth transistor Tr5 is connected to the anode terminal of the display element 20. Further, the first terminal of the fifth transistor Tr5 is connected to the first terminal of the sixth transistor Tr6 and the first terminal of the storage capacitor Cts via a node n4. The second terminal of the fifth transistor Tr5 is connected to the first terminal of the first transistor Tr1 and the first terminal of the second transistor Tr2 via the node n3. Note that the fifth transistor Tr5 is, for example, a p-channel transistor.

The first terminal of the sixth transistor Tr6 is connected to the first terminal of the fifth transistor Tr5, the first terminal of the storage capacitor Cst and the anode terminal of the display element 20 via the node n4. The second terminal of the sixth transistor Tr6 is connected to a power line for supplying an initialization voltage Vini. Note that the sixth transistor Tr6 is, for example, an n-channel transistor.

The first terminal of the seventh transistor Tr7 is connected to the second terminal of the second transistor Tr2, the second terminal of the third transistor Tr3 and the first terminal of the fourth transistor Tr4 via the node n1. The second terminal of the seventh transistor Tr7 is connected to a power line for supplying a power supply voltage VSH. Note that the seventh transistor Tr7 is, for example, an n-channel transistor.

Further, as shown in FIG. 13, the gate terminal of the first transistor Tr1 is connected to a gate signal line for supplying a gate signal Scan2. The gate terminal of the third transistor Tr3 is connected to a gate signal line for supplying a gate signal Scan1. The gate terminals of the fourth to sixth transistors Tr4 to Tr6 are connected to control signal lines for supplying control signals EM. The gate terminal of the seventh transistor Tr7 is connected to a gate signal line for supplying a gate signal Scan3.

The first terminal of the storage capacitor Cst is connected to the first terminal of the fifth transistor Tr5, the first terminal of the sixth transistor Tr6 and the anode terminal of the display element 20 via the node n4. The second terminal of the storage capacitor Cst is connected to the gate terminal of the second transistor Tr2 and the first terminal of the third transistor Tr3 via the node n2.

The anode terminal of the display element 20 is connected to the first terminal of the fifth transistor Tr5. The anode terminal of the display element 20 is connected to the first terminal of the sixth transistor Tr6 and the first terminal of the storage capacitor Cst via the node n4. The cathode terminal of the display element 20 is connected to a power line for supplying a power supply voltage VSSEL. The power supply voltage VDDEL described above corresponds to the anode voltage to be supplied to the display element 20, and the power supply voltage VSSEL corresponds to the cathode voltage to be supplied to the display element 20.

FIG. 14 shows an example of the circuit configuration of the pixel circuit 210 disposed in the second display area DA2. As shown in FIG. 14, the pixel circuit 210 is a 4Tr1C pixel circuit constituted by four transistors (hereinafter referred to as the first to fourth transistors) Tr1 to Tr4 and one storage capacitor Cst.

In the following descriptions, one of the source and drain terminals of each of the first to fourth transistors Tr1 to Tr4 shown in FIG. 14 is referred to as the first terminal and the other as the second terminal. Further, one of the terminals of the storage capacitor Cst (realized by a capacitive element) shown in FIG. 14 is referred to as the first terminal and the other terminal as the second terminal.

The first terminal of the first transistor Tr1 is connected to the gate terminal of the second transistor Tr2 and the second terminal of the storage capacitor Cst via the node n1. The second terminal of the first transistor Tr1 is connected to the data signal line for supplying the data signal Data. Note that the first transistor Tr1 is, for example, an n-channel transistor.

The second transistor Tr2 corresponds to a drive transistor (DRT) that supplies a current to the display element 20 contained in the subpixel SP (that is, the display element 20 driven by the pixel circuit 210). The first terminal of the second transistor Tr2 is connected to the first terminal of the third transistor Tr3, the first terminal of the storage capacitor Cst, and the anode terminal of the display element 20 via the node n2. The second terminal of the second transistor Tr2 is connected to the first terminal of the fourth transistor Tr4. Note that the second transistor Tr2 is, for example, an n-channel transistor.

The first terminal of the third transistor Tr3 is connected to the first terminal of the second transistor Tr2 and the anode terminal of the display element 20 via the node n2. Further, the first terminal of the third transistor Tr3 is connected to the first terminal of the storage capacitor Cst. The second terminal of the third transistor Tr3 is connected to the power line supplying the initialization voltage Vini. Note that the third transistor Tr3 is, for example, an n-channel transistor.

The first terminal of the fourth transistor Tr4 is connected to the second terminal of the second transistor Tr2. The second terminal of the fourth transistor Tr4 is connected to the power line for supplying the power supply voltage VDDEL. Note that the fourth transistor Tr4 is, for example, a p-channel transistor.

As shown in FIG. 14, the gate terminal of the first transistor Tr1 and the gate terminal of the third transistor Tr3 are connected to the gate signal line for supplying the gate signal Scan1. The gate terminal of the fourth transistor Tr4 is connected to the control signal line for supplying the control signal EM.

The first terminal of the storage capacitor Cst is connected to the first terminal of the second transistor Tr2 and the anode terminal of the display element 20 via the node n2. Further, the first terminal of the storage capacitor Cst is connected to the first terminal of the third transistor Tr3. The second terminal of the storage capacitor Cst is connected to the first terminal of the first transistor Tr1 and the gate terminal of the second transistor Tr2 via the node n1.

The anode terminal of the display element 20 is connected to the first terminal of the second transistor Tr2, the first terminal of the third transistor Tr3 and the first terminal of the storage capacitor Cst via the node n2. The cathode terminal of the display element 20 is connected to the power line for supplying the power supply voltage VSSEL.

As described above, the display device DSP of this embodiment includes a base 10, a plurality of subpixels SP (first pixels) disposed in a first display area DA1 included in the display area DA on the base 10, and a plurality of subpixels SP (second pixels) disposed in a second display area DA2 included in the display area DA. Here, the number of transistors which constitute the pixel circuits 210 (second pixel circuits) contained in the subpixels SP arranged in the second display area DA2 is less than the number of transistors which constitute the pixel circuits 200 (first pixel circuits) contained in the subpixels SP arranged in the first display area DA1.

Note that in this embodiment, the first display area DA1 is assumed as an area disposed in a position not overlapping the camera 100, and the second display area DA2 as an area disposed in a position overlapping the camera 100.

With the above-described configuration of this embodiment, the area of the region occupied by the pixel circuits 210 per unit area of the second display area DA2 can be made smaller than the area occupied by the pixel circuits 200 per unit area of the first display area DA1, and therefore the light transmittance in the second display area DA2 can be improved.

More specifically, in the second display area DA2, a transmitting portion 220 can be disposed, which is the region overlapping the apertures AP of the rib 5 and corresponds to the region where the pixel circuit 210, the display element (lower electrodes LE, light emitting layer OR, and upper electrode UE), the cap layer CP and the sealing layer SE are not formed. In the transmitting portion 220 having such a configuration, high light transmittance can be achieved, and therefore light transmittance in the second display area DA2 can be improved.

Further, in this embodiment, since there is no need to thin out the pixels PX (subpixels SP1, SP2 and SP3), the resolution in the second display area DA2 is not reduced.

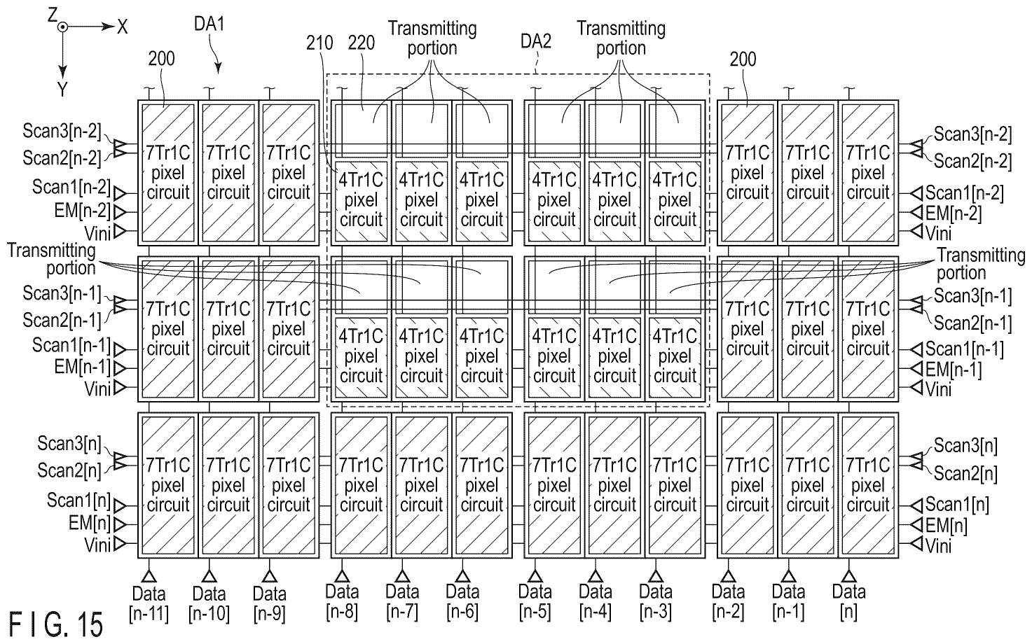

Here, FIG. 15 is a diagram schematically showing the arrangement of various wiring lines connected to the pixel circuits 200 arranged in the first display area DA1 and the pixel circuits 210 arranged in the second display area DA2. Note that in FIG. 15, only the data signal lines that supply the data signal Data, the gate signal lines that supply the gate signals Scan1 to Scan3, the control signal lines that supply the control signal EM, and the power supply lines that supply the initialization voltage Vini are shown.

As shown in FIG. 15, the data signal lines that supply the data signals Data are disposed to be aligned along the first direction X and to extend along the second direction Y. The gate signal lines supplying the gate signals Scan1 to Scan3, the control signal lines supplying the control signal EM, and the power supply lines supplying the initialization voltage Vini are arranged to be aligned along the second direction Y and to extend along the first direction X.

In this embodiment, the transmitting portion 220 is arranged in the second display area DA2 as described above, but if a number of wiring lines are formed (in the circuit layer 12) in the transmitting portion 220, it is considered that the light transmittance in the transmitting portion 220 may be reduced.

In contrast, for example, according to the pixel circuit 200 shown in FIG. 13 and the pixel circuit 210 shown in FIG. 14, the gate signal line that supplies the gate signal Scan1, the control signal line that supplies the control signal EM, and the power supply line that supplies the initialization voltage Vini are common in the pixel circuit 200 and 210. Therefore, it suffices if only the gate signal lines for supplying the gate signals Scan2 and Scan3 are formed (arranged) in the transmitting portion 220. Thus, it is possible to suppress the light transmittance in the transmitting portion 220 from being reduced by the influence of the wiring lines connected to the pixel circuits 200.

In other words, in this embodiment, the pixel circuits 200 and 210 are mounted in such a way that part of the plurality of wiring lines connected to the pixel circuit 200 are connected to the pixel circuits 210 (that is, there are more signals usable in common). With this configuration, it is possible to further improve the light transmittance in the second display area DA2.

The operations of the pixel circuits 200 (7Tr1C pixel circuits) shown in FIG. 13 and the pixel circuits 210 (4Tr1C pixel circuit) shown in FIG. 14 explained in this embodiment will now be briefly described.

Here, note that the transistors which constitute the pixel circuits 200 and 210 includes n-channel transistors and p-channel transistors. The n-channel transistors are switching elements each to be set in an off state (non-conducting state) when a low (level) signal is supplied to the respective gate terminal, and those each to be set in an on state when a high (level) signal is supplied to the respective gate terminal. On the other hand, the p-channel transistors are switching elements each to be set in the off state (non-conducting state) when a high (level) signal is supplied to the respective gate terminal and those each to be sent in the on state (conducting state) when a low (level) signal is supplied to the respective gate terminal.

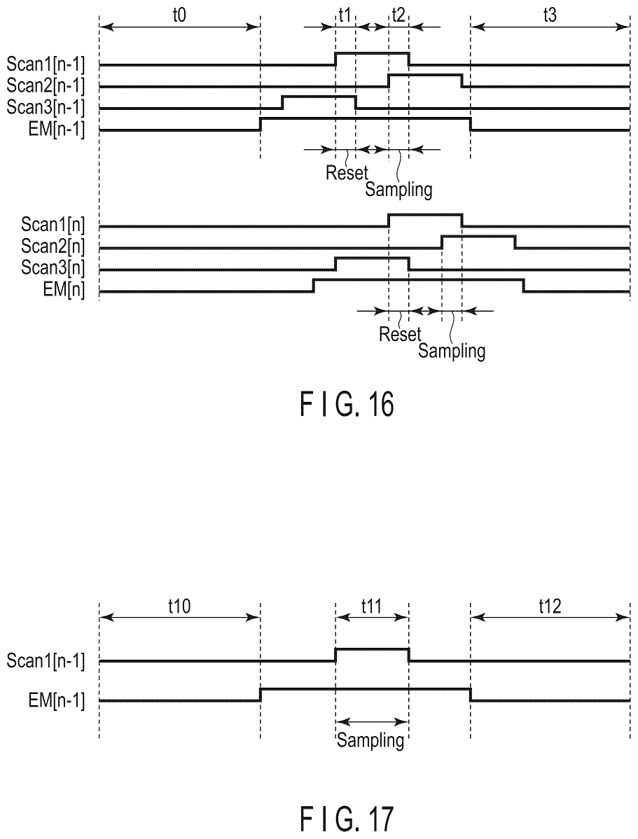

First, with reference to FIG. 16, the operation of the pixel circuits 200 shown in FIG. 13 will be explained. FIG. 16 is a timing chart showing an example of outputting of gate signals Scan1 to Scan3 and control signal EM to the pixel circuits 200 (subpixels SP disposed in the first display area DA1) arranged in a row n-1 and a row n shown in FIG. 15. Here, the operation of the pixel circuits 200 disposed in the row n-1 will be described.

In a time period to shown in FIG. 16, the control signal EM is at low, and therefore the fourth transistor Tr4 and the fifth transistor Tr5 of the seven transistors in the respective pixel circuit 200 are in the on state and the sixth transistor Tr6 is in the off state.

In the period to, the gate signals Scan1 to Scan3 are at low, the first transistor Tr1, the third transistor Tr3 and the seventh transistor Tr7 are in the off state.

With this configuration, the current controlled by the gate voltage of the second transistor Tr2 (the voltage supplied to the gate terminal of the second transistor Tr2 based on the data signal Data of the previous frame) is maintained to be being supplied to the display element 20 (OLED).

Note that the control signal EM is switched from low to high at the timing when the period to ends.

Next, in a time period t1 shown in FIG. 16, the control signal EM is at high, and therefore the fourth transistor Tr4 and the fifth transistor Tr5 are in the off state and the sixth transistor Tr6 is in the on state. In this case, the initialization voltage Vini is supplied to the node n4 via the sixth transistor Tr6. But, since the initialization voltage Vini is set to a value at which no current flows to the display element 20, no current flows to the display element 20 in the period t1.

Further, at the timing when the period t1 starts, the gate signal Scan1 is switched from low to high. Therefore, in the period t1, the third transistor Tr3 is set in the on state. Furthermore, after the end of the period to and before the start of the period t1, the gate signal Scan3 is switched from low to high. Therefore, in the period t1, the seventh transistor Tr7 is in the on state. With this configuration, such a state is created that the power supply voltage VSH is supplied to the gate terminal of the second transistor Tr2 via the seventh transistor Tr7 and the third transistor Tr3. In this case, a voltage of VSH-Vini is applied to the storage capacitor Cst (between the first and second terminals of the capacitor Cst), and the information of the previous frame is reset.

Note that at the timing when the period t1 ends, the gate signal Scan3 is switched from high to low.

Next, at the timing when a time period t2 shown in FIG. 16 starts, the gate signal Scan2 is switched from low to high. Therefore, in the period t2, the first transistor Tr1 is set in the on state. Further, in the period t2, the gate signal Scan3 is at low, the seventh transistor Tr7 is in the off state.

In this case, to the gate terminal of the second transistor Tr2, the data signal Data (that is, the voltage Vdata corresponding to the data signal Data) and the threshold voltage Vth of the second transistor Tr2 (that is, the voltage corresponding to Vdata+Vth) are supplied through via the first transistor Tr1, the second transistor Tr2 and the third transistor Tr3. With this configuration, a voltage of Vdata+Vth-Vini is applied to the storage capacitor Cst, and information on Vdata and Vth are written to the storage capacitor Cst.

Note that at the timing when the period t2 ends, the gate signal Scan1 is switched from high to low.

Next, in a time period t3 shown in FIG. 16, the gate signal Scan1 is at low, and therefore the third transistor Tr3 is in the off state. Further, since the gate signal Scan2 is already switched from high to low before the period t3 starts, the first transistor Tr1 is in the off state. Furthermore, the control signal EM is switched from high to low at the timing when the period t3 starts. With this configuration, the fourth transistor Tr4 and the fifth transistor Tr5 are set in the on state, and the sixth transistor Tr6 is set in the off state.

Here, when it is assumed that the first terminal of the second transistor Tr2 is the source terminal, the voltage Vgs between the gate terminal and the source terminal (the node n2 to node n3) of the second transistor Tr2 is the voltage of the storage capacitor Cst (that is, Vdata+Vth-Vini). In this case, the second transistor Tr2 is set in the on state and a current flows from the power line connected to the second terminal of the fourth transistor Tr4 (, that is, the power line for supplying the power supply voltage Vdel) toward the node n4. Accordingly, the potential of the node n4 begins to rise, and when the potential exceeds the threshold of the display element 20 (OLED), current begins to flow to the display element 20, thus starting light emission in the display element 20. Finally, when a current Ioled flowing in the display element 20 reaches an output current given by the second transistor Tr2 (, that is, an output current in a saturation region of the second transistor Tr2) Idrt, the potential rise of the node n4 stops and the display element 20 is set in a steady state of light emission.

Here, when the voltage between the gate and source terminals of the second transistor Tr2, expressed by: Vgs=Vdata+Vth-Vini, is substituted into the TFT saturation formula: Idrt=1/2 Cox*μ* W/L*(Vgs-Vth)², the following can be obtained: Idrt (=Ioled)=1/2 Cox*μ*W/L*(Vdata-Vini)². Here, Cox represents the gate capacitance per unit area, u for the carrier mobility, W for the channel width of the second transistor Tr2, and L for the channel length of the second transistor Tr2.

According to the above, Idrt becomes a value independent of the threshold voltage Vth of the second transistor Tr2 (that is, a current independent of the threshold voltage Vth of the second transistor Tr2 flows to the display element 20), and therefore it is confirmed that the effect of the variation of the threshold voltage Vth on Idrt can be eliminated.

In other words, it can be said that the pixel circuit 200 (7Tr1C pixel circuit) shown in FIG. 13 has a function for correcting variations in threshold voltage Vth of the second transistor Tr2 (, which will be hereinafter referred to as a Vth correction function). The Vth correction function is mainly realized by the first transistor Tr1 and the seventh transistor Tr7.

The operation of the pixel circuits 200 arranged in the row n-1 shown in FIG. 16 is described here, and the operation of the pixel circuits 200 arranged in the row n is similar; therefore a detailed description thereof is omitted here.

Next, with reference to FIG. 17, the operation of the pixel circuits 210 shown in FIG. 14 will be explained. FIG. 17 is a timing chart showing an example of outputting of the gate signal Scan1 and the control signal EM to the pixel circuits 210 (the subpixels SP disposed in the second display area DA2) disposed in the row n-1 shown in FIG. 15.

In a time period t10 shown in FIG. 17, the control signal EM is at low, and therefore the fourth transistor Tr4 of the four transistors contained in the pixel circuit 210 is in the on state. Further, in the period t10, the gate signal Scan1 is at low, and therefore the first transistor Tr1 and the third transistor Tr3 are in the off state.

With this configuration, such a state is maintained that the current controlled by the gate voltage of the second transistor Tr2 (, that is, the voltage supplied to the gate terminal of the second transistor Tr2 based on the data signal Data of the previous frame) is being supplied to the display element 20 (OLED).

Note that at the timing when the period t10 ends, the control signal EM is switched from low to high.

Next, in the period t11 shown in FIG. 17, the control signal EM is at high, and therefore the fourth transistor Tr4 is in the off state. In this case, the current flowing to the display element 20 is 0.

At the timing when the period t11 starts, the gate signal Scan1 is switched from low to high. Therefore, in the period t11, the first transistor Tr1 and the third transistor Tr3 are set in the on state.

In this case, the initialization voltage Vini is supplied to the node n2 via the third transistor Tr3, but the initialization voltage Vini is set to a value at which no current flows to the display element 20, and therefore no current flows to the display element 20 during the period t11.

In addition, the data signal Data (the voltage Vdata corresponding to the data signal Data) is supplied to the node n1 from the data signal line via the first transistor Tr1. With this configuration, a voltage of Vdata-Vini is applied to the storage capacitor Cst, and information on Vdata is written to the storage capacitor Cst.

Note that at the timing when the period t11 ends, the gate signal Scan1 is switched from high to low.

Next, in a time period t12 shown in FIG. 17, the gate signal Scan1 is at low, and therefore the first transistor Tr1 and the third transistor Tr3 are in the off state. Further, the control signal EM is switched from high to low at the timing when period t12 starts. Therefore, the fourth transistor Tr4 is set in the on state.

Here, when it is assumed that the first terminal of the second transistor Tr2 is the source terminal, the voltage Vgs between the gate terminal and the source terminal of the second transistor Tr2 (, that is, node n1 to node n2) becomes the voltage of the storage capacitor Cst (, that is, Vdata-Vini). In this case, the second transistor Tr2 is set in the on state and a current flows from the power line connected to the second terminal of the fourth transistor Tr4, (that is the power line for supplying the power supply voltage Vdel) toward the node n2. Accordingly, the potential of node n2 begins to rise, and when the potential exceeds the threshold of the display element 20 (OLED), current begins to flow to the display element 20, thereby starting light emission in the display element 20. Finally, when the current Ioled flowing in the display element 20 reaches the output current Idrt given by the second transistor Tr2, the potential rise of the node n2 stops and the display element 20 is set in a steady state of light emission.

Here, the voltage between the gate and source terminals of the second transistor Tr2, expressed by Vgs=Vdata-Vini, is substituted into the TFT saturation formula: Idrt=1/2 Cox*μ*W/L*(Vgs-Vth)², the following equation is obtained:

Idrt (=Ioled)=1/2 Cox*μ*W/L*(Vdata-Vini-Vth)².

According to the above, Idrt becomes a value dependent of the threshold voltage Vth of the second transistor Tr2 (that is, a current dependent of the threshold voltage Vth of the second transistor Tr2 flows to the display element 20), and it is confirmed that Idrt is affected by the variation of the threshold voltage Vth.

In other words, it can be said that the pixel circuits 210 (4Tr1C pixel circuit) shown in FIG. 14, unlike the pixel circuits 200 shown in FIG. 13, does not have the Vth correction function described above.

Note that even with the same data signal Data (Vdata), there is a difference in Idrt (Ioled) due to the presence or absence of the Vth correction function between the pixel circuit 200 and pixel circuit 210. As a result, it may cause a difference in luminance between the first display area DA1 and the second display area DA2. In this case, for example, by biasing and correcting the data signal Data (Vdata signal), the difference in luminance between the first display area DA1 and the second display area DA2 may be eliminated.

Further, according to FIGS. 16 and 17 explained above, the pixel circuits 200 and 210 are driven by the gate signal Scan1 and control signal EM, which are output (supplied) at the same timing from the shared gate signal lines and control signal lines. In this embodiment, such combination of pixel circuits 200 and 210 is adopted that part of a plurality of wiring lines are shared to be able to drive the circuits by signals supplied at the same timing. Thus, the number of wiring lines disposed in the transmitting portions 220 can be reduced and the light transmittance in the second display area DA2 can be improved.

Note that this embodiment is explained in connection with the case where the pixel circuits 200 arranged in the first display area DA1 are each the 7Tr1C pixel circuit shown in FIG. 13 and the pixel circuits 210 arranged in the second display area DA2 are each the 4Tr1C pixel circuits shown in FIG. 14. Here, in order to improve the transmittance, the pixel circuits 200 and 210 should be configured so that the area occupied by the pixel circuits 210 per unit area is smaller than the area occupied by the pixel circuits 200. More specifically, the pixel circuits 210 should by constituted by fewer transistors than the case of the pixel circuits 200, and the pixel circuits 200 and 210 are not limited to the circuit configurations shown in FIGS. 13 and 14.

Other examples of the circuit configurations of the pixel circuits 200 and 210 will now be described. In FIGS. 13 and 14 referred to above, the case where the drive transistors are of an n-channel type is described, whereas, here, the case where the drive transistors are of a p-channel type will be described.

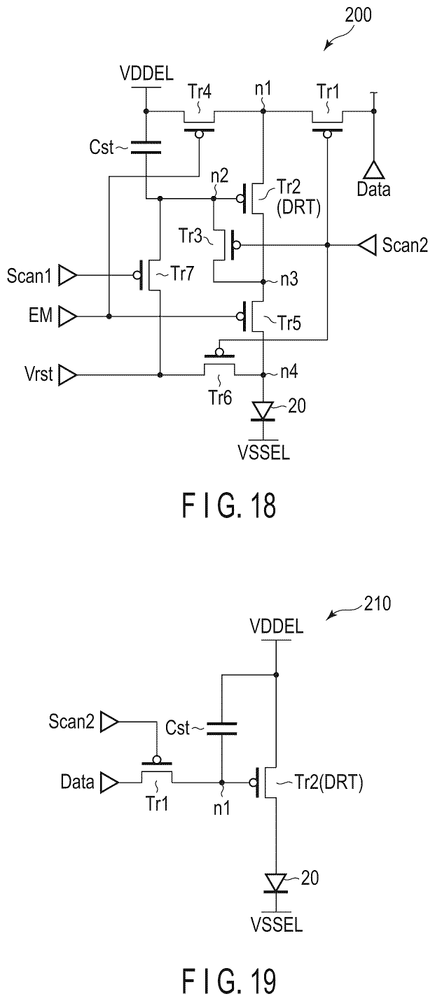

FIG. 18 shows another example of the circuit configuration of the pixel circuits 200 disposed in the first display area DA1. As shown in FIG. 18, the pixel circuit 200 is a 7Tr1C pixel circuit constituted by seven transistors (hereinafter referred to as the first to seventh transistors) and one storage capacitor Cst.

In the following descriptions, one of the source and drain terminals of each of the first to seventh transistors Tr1 to Tr7 shown in FIG. 18 is referred to as the first terminal and the other as the second terminal. Further, one of the terminals of the storage capacitor Cst (the capacitive element that realizes the storage capacitor Cst) shown in FIG. 18 is referred to as the first terminal and the other terminal as the second terminal.

The first terminal of the first transistor Tr1 is connected to the second terminal of the second transistor Tr2 and the second terminal of the fourth transistor via the node n1. The second terminal of the first transistor Tr1 is connected to the data signal line for supplying the data signal Data. Note that the first transistor Tr1 is, for example, a p-channel transistor.

The second transistor Tr2 corresponds to a drive transistor (DRT) that supplies a current to the display element 20 contained in the subpixel SP (, that is, the display element 20 driven by the pixel circuit 200). The first terminal of the second transistor Tr2 is connected to the second terminal of the third transistor Tr3 and the second terminal of the fifth transistor Tr5 via the node n3. The second terminal of the second transistor Tr2 is connected to the first terminal of the first transistor Tr1 and the second terminal of the fourth transistor Tr4 via the node n1. Note that the second transistor Tr2 is, for example, a p-channel transistor.

The first terminal of the third transistor Tr3 is connected to the gate terminal of the second transistor Tr2, the first terminal of the seventh transistor Tr7 and the second terminal of the storage capacitor Cst via the node n2. The second terminal of the third transistor Tr3 is connected to the first terminal of the second transistor Tr2 and the second terminal of the fifth transistor Tr5 via the node n3. Note that the third transistor Tr3 is, for example, a p-channel transistor.

The first terminal of the fourth transistor Tr4 is connected to the first terminal of the first transistor Tr1 and the second terminal of the second transistor Tr2 via the node n1. The second terminal of the fourth transistor Tr4 is connected to the first terminal of the storage capacitor Cst. The second terminal of the fourth transistor Tr4 is connected to the power line for supplying the power supply voltage VDDEL. Note that the fourth transistor Tr4 is, for example, a p-channel transistor.

The first terminal of the fifth transistor Tr5 is connected to the first terminal of the sixth transistor Tr6 and the anode terminal of the display element 20 via the node n4. The second terminal of the fifth transistor Tr5 is connected to the first terminal of the second transistor Tr2 and the second terminal of the third transistor Tr3 via the node n3. Note that the fifth transistor Tr5 is, for example, a p-channel transistor.

The first terminal of the sixth transistor Tr6 is connected to the first terminal of the fifth transistor Tr5 and the anode terminal of the display element 20 via the node n4. The second terminal of the sixth transistor Tr6 is connected to the second terminal of the seventh transistor Tr7. The second terminal of the sixth transistor Tr6 is connected to a power line for supplying a reset voltage Vrst. Note that the sixth transistor Tr6 is, for example, a p-channel transistor.

The first terminal of the seventh transistor Tr7 is connected to the gate terminal of the second transistor Tr2 and the first terminal of the third transistor Tr3 via the node n2. Further, the first terminal of the seventh transistor Tr7 is connected to the second terminal of the storage capacitor Cst. The second terminal of the seventh transistor Tr7 is connected to the second terminal of the sixth transistor Tr6. Further, the second terminal of the seventh transistor Tr7 is connected to the power line supplying the reset voltage Vrst. Note that the seventh transistor Tr7 is, for example, a p-channel transistor.

Moreover, as shown in FIG. 18, the gate terminals of the first transistor Tr1, the third transistor Tr3 and the sixth transistor Tr6 are connected to the gate signal line for supplying the gate signal Scan2. The gate terminals of the fourth transistor Tr4 and the fifth transistor Tr5 are connected to the control signal line for supplying the control signal EM. The gate terminal of the seventh transistor Tr7 is connected to the gate signal line for supplying the gate signal Scan1.

The first terminal of the storage capacitor Cst is connected to the second terminal of the fourth transistor Tr4. The first terminal of the storage capacitor Cst is connected to the power supply line for supplying the power supply voltage VDDEL. The second terminal of the storage capacitor Cst is connected to the gate terminal of the second transistor Tr2 and the first terminal of the third transistor Tr3 via the node n2. Further, the second terminal of the storage capacitor Cst is connected to the first terminal of the seventh transistor Tr7.

The anode terminal of the display element 20 is connected to the first terminal of the fifth transistor Tr5 and the first terminal of the sixth transistor Tr6 via the node n4. The cathode terminal of the display element 20 is connected to the power line for supplying the power supply voltage VSSEL. The power supply voltage VDDEL described above corresponds to the anode voltage to be supplied to the display element 20, and the power supply voltage VSSEL corresponds to the cathode voltage to be supplied to the display element 20.

FIG. 19 shows another example of the circuit configuration of the pixel circuits 210 disposed in the second display area DA2. As shown in FIG. 19, the pixel circuits 210 are each a 2Tr1C pixel circuit constituted by two transistors (hereinafter referred to as the first and second transistors) Tr1 and Tr2 and one storage capacitor Cst.

In the following descriptions, one of the source and drain terminals of each of the first and second transistors Tr1 and Tr2 shown in FIG. 19 is referred to as the first terminal and the other as the second terminal. Further, one of the terminals of the storage capacitor Cst (the capacitive element that realizes the storage capacitor Cst shown in FIG. 19) is referred to as the first terminal and the other terminal as the second terminal.

The first terminal of the first transistor Tr1 is connected to the gate terminal of the second transistor Tr2 and the second terminal of the storage capacitor Cst via the node n1. The second terminal of the first transistor Tr1 is connected to the data signal line for supplying the data signal Data. Note that the first transistor Tr1 is, for example, a p-channel transistor.

The second transistor Tr2 corresponds to a drive transistor (DRT) that supplies a current to the display element 20 contained in the subpixel SP (that is, the display element 20 to be driven by the pixel circuit 210). The first terminal of the second transistor Tr2 is connected to the anode terminal of the display element 20. The second terminal of the second transistor Tr2 is connected to the first terminal of the storage capacitor Cst. Further, the second terminal of the second transistor Tr2 is connected to the power line for supplying the power supply voltage VDDEL. Note that the second transistor Tr2 is, for example, a p-channel transistor.

As shown in FIG. 19, the gate terminal of the first transistor Tr1 is connected to the gate signal line for supplying the gate signal Scan2.

The first terminal of the storage capacitor Cst is connected to the second terminal of the second transistor Tr2. Further, the first terminal of the storage capacitor Cst is connected to the power supply line for supplying the power supply voltage VDDEL. The second terminal of the storage capacitor Cst is connected to the first terminal of the first transistor Tr1 and the gate terminal of the second transistor Tr2 via the node n1.

The anode terminal of the display element 20 is connected to the first terminal of the second transistor Tr2. The cathode terminal of the display element 20 is connected to the power line for supplying the power supply voltage VSSEL.

According to the circuit configuration shown in FIGS. 18 and 19 provided above, the number of transistors constituting the pixel circuits 210 disposed in the second display area DA2 can be smaller than the number of transistors constituting the pixel circuits 200 disposed in the first display area DA1, and thus the transmitting portions 220 can be arranged in the second display area DA2. Therefore, it is possible to improve the light transmittance in the second display area DA2.

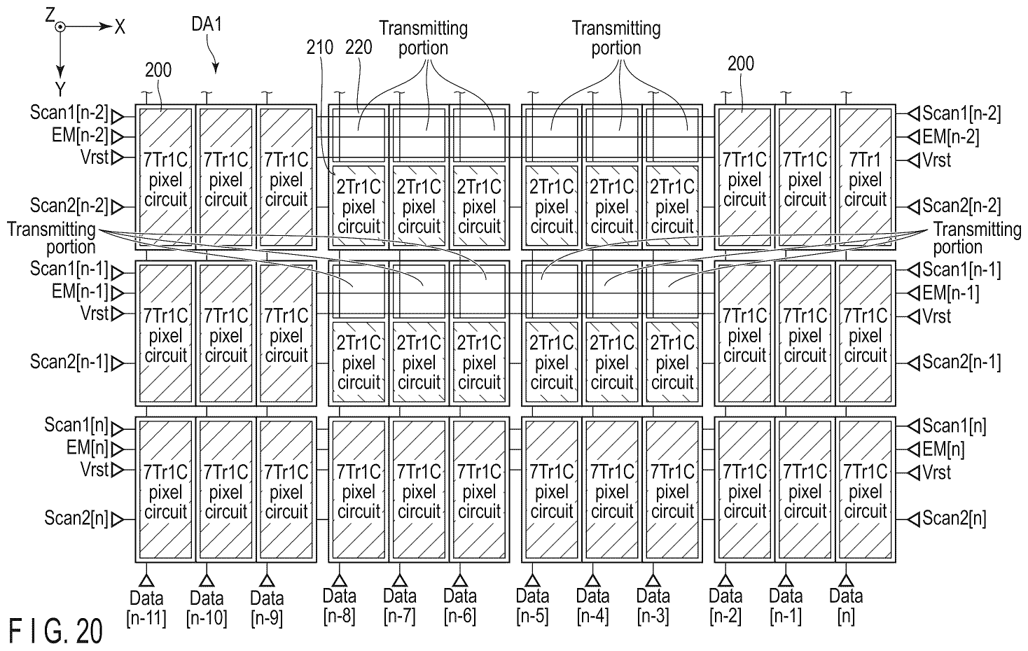

Note that when the pixel circuits 200 whose configuration is shown in FIG. 18 are disposed in the first display area DA1 and the pixel circuits 210 whose configuration is shown in FIG. 19 are arranged in the second display area DA2, it is possible to share the gate signal lines that supply the gate signal Scan2 in the pixel circuits 200 and 210, as shown in FIG. 20.

The operation of the pixel circuit 200 (7Tr1C pixel circuit) shown in FIG. 18 and the pixel circuit 210 (2Tr1C pixel circuit) shown in FIG. 19 described above will now be briefly explained.

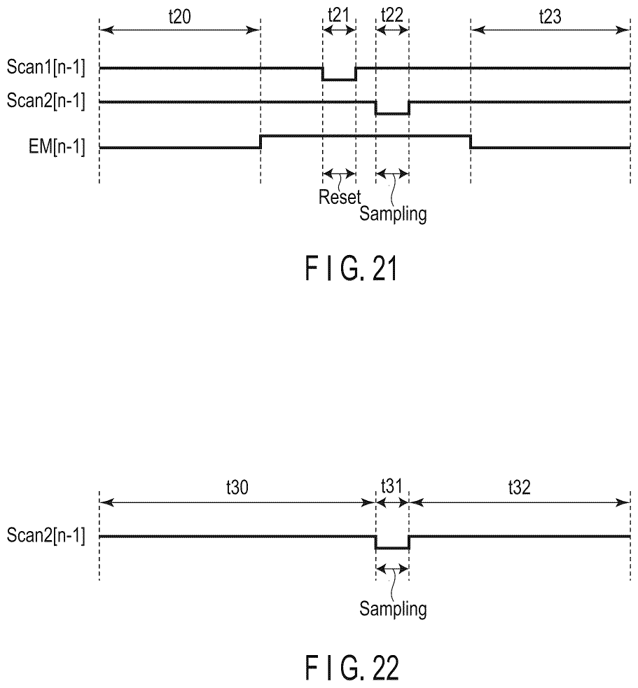

First, the operation of the pixel circuit 200 shown in FIG. 18 will be explained with reference to FIG. 21. FIG. 21 is a timing chart showing an example of outputting of the gate signals Scan1 and Scan2 and the control signal EM to the pixel circuits 200 (subpixels SP disposed in the first display area DA1) disposed in the row n-1 shown in FIG. 20.

In a time period t20 shown in FIG. 21, the control signal EM is at low, and therefore the fourth transistor Tr4 and the fifth transistor Tr5 of the seven transistors in the pixel circuit 200 are in the on state.

Further, in the period t20, the gate signals Scan1 and Scan2 are at high, the first transistor Tr1, the third transistor Tr3, the sixth transistor Tr6 and the seventh transistor Tr7 are in the off state.

With this configuration, such a state is maintained that the current controlled by the gate voltage of the second transistor Tr2 (the voltage supplied to the gate terminal of the second transistor Tr2 based on the data signal Data of the previous frame) is being supplied to the display element 20 (OLED).

Note that at the timing when the period t20 ends, the control signal EM is switched from low to high.

Next, in a time period t21 shown in FIG. 21, the control signal EM is at high, the fourth transistor Tr4 and the fifth transistor Tr5 are in the off state. In this case, the current flowing to the display element 20 is 0.

Further, at the timing when the period t21 starts, the gate signal Scan1 is switched from high to low. Therefore, in the period t21, the seventh transistor Tr7 is in the on state.

In this case, the reset voltage Vrst is supplied to the gate terminal of the second transistor Tr2 via the seventh transistor Tr7. Further, a voltage of Vrst-VDDEL is applied to the storage capacitor Cst, and thus the information in the previous frame is reset.

Note that at the timing when the period t21 ends, the gate signal Scan1 is switched from low to high.

Next, in a time period t22 shown in FIG. 21, the gate signal Scan1 is at high, and therefore the seventh transistor Tr7 is in the off state. Further, at the timing when the period t22 starts, the gate signal Scan2 is switched from high to low. Therefore, the first transistor Tr1, the third transistor Tr3 and the sixth transistor Tr6 are set in the on state.

In this case, to the gate terminal of the second transistor Tr2, the data signal Data (the voltage Vdata corresponding to the data signal Data) and the threshold voltage Vth of the second transistor Tr2 (, that is, the voltage corresponding to Vdata+Vth) are supplied via the first transistor Tr1, the second transistor Tr2 and the third transistor Tr3. With this configuration, a voltage of Vdata+Vth-VDDEL is applied to the storage capacitor Cst, and the information on Vdata and Vth is written to the storage capacitor Cst.

Further, a reset voltage Vrst is supplied to the node n4 (the anode terminal of the display element 20) via the sixth transistor Tr6, and the anode is reset.

Note that at the timing when the period t22 ends, the gate signal Scan2 is switched from low to high.

Next, in a period t23 shown in FIG. 21, the gate signal Scan2 is at high, and therefore the first transistor Tr1, the third transistor Tr3 and the sixth transistor Tr6 are in the off state. Further, at the timing when the period t23 starts, the control signal EM is switched from high to low. Therefore, the fourth transistor Tr4 and the fifth transistor Tr5 are set in the on state.

Here, when it is assumed that the second terminal of the second transistor Tr2 is the source terminal, a voltage Vgs between the gate terminal and the source terminal (node n1 to node n2) of the second transistor Tr2 is at the voltage of the storage capacitor Cst (, that is, Vdata+Vth-VDDEL). In this case, the second transistor Tr2 is set in the on state and current flows from the power line connected to the second terminal of the fourth transistor Tr4 (the power line for supplying the power supply voltage VDDEL) toward the node n4. Accordingly, the potential of the node n4 begins to rise, and when the potential exceeds the threshold of the display element 20 (OLED), current begins to flow to the display element 20, thereby starting the light emission in the display element 20. Finally, when the current Ioled flowing in the display element 20 reaches the output current Idrt given by the second transistor Tr2 (the output current in the saturation region of the second transistor Tr2), the potential rise of the node n4 stops and the display element 20 is set in the steady state of light emission.

Here, the voltage between the gate and source terminals of the second transistor Tr2, represented by: Vgs=Vdata+Vth−VDDEL is substituted into the TFT saturation formula: Idrt=1/2Cox*μ*W/L*(Vgs-Vth) 2, the following equation is obtained:

$$Idrt ( = Ioled ) = 1 / 2 Cox * μ * W / L * {( Vdata - VDDEL )}^{2} .$$

According to the above, Idrt becomes a value that is not dependent on the threshold voltage Vth of the second transistor Tr2 (in other words, a current not dependent on the threshold voltage Vth of the second transistor Tr2 flows to the display element 20), and it is confirmed that the effect of the variation in the threshold voltage Vth on Idrt can be eliminated.

In other words, it can be said that the pixel circuit 200 (7Tr1C pixel circuit) shown in FIG. 18 has a function of correcting the variation in the threshold voltage Vth of the second transistor Tr2 (Vth correction function).

Next, with reference to FIG. 22, the operation of the pixel circuit 210 shown in FIG. 19 will be described. FIG. 22 is a timing chart showing an example of outputting of the gate signal Scan2 to the pixel circuits 210 (the subpixel SP disposed in the second display area DA2) disposed in the row n-1 shown in FIG. 20.

In a period t30 shown in FIG. 22, the gate signal Scan2 is at high, and therefore the first transistor Tr1 of the two transistors in the pixel circuit 210 is in the off state.

With this configuration, such a state is maintained that the current controlled by the gate voltage of the second transistor Tr2 (the voltage supplied to the gate terminal of the second transistor Tr2 based on the data signal Data of the previous frame) is supplied to the display element 20 (OLED).

Next, at the timing when a time period t31 shown in FIG. 22 starts, the gate signal Scan2 is switched from high to low. Therefore, in the period t31, the first transistor Tr1 is set in the on state. In this case, the data signal Data (the voltage Vdata corresponding to the data signal Data) is supplied to the node n1 from the data signal line via the first transistor Tr1. With this configuration, when assuming that the second terminal of the second transistor Tr2 is the source terminal, a voltage of Vdata−VDDEL is applied to the storage capacitor Cst (between the gate terminal and the source terminal of the second transistor Tr2), and information on Vdata is written to the storage capacitor Cst.

Note that at the timing when period t31 ends, the gate signal Scan1 is switched from low to high.

Next, in a time period t32 shown in FIG. 22, the gate signal Scan2 is at high, and therefore the first transistor Tr1 is in the off state. In this case, the voltage Vgs between the gate and source terminals of the second transistor Tr2 is at the voltage of the storage capacitor Cst (Vdata−VDDEL). Here, the second transistor Tr2 is set in the on state, and current flows from the power supply line connected to the second terminal (source terminal) of the second transistor Tr2 (, that is, the power supply line for supplying the power supply voltage VDDEL) toward the anode terminal of the display element 20. Accordingly, the potential of the node between the first terminal (drain terminal) of the second transistor Tr2 and the anode terminal of the display element 20 begins to rise, and when the potential exceeds the threshold of the display element 20 (OLED), current begins to flow to the display element 20, thereby starting the light emission in the display element 20. Finally, when the current Ioled flowing in the display element 20 reaches the output current Idrt given by the second transistor Tr2, the potential rise of the node between the first terminal (drain terminal) of the second transistor Tr2 and the anode terminal of the display element 20 stops and the display element 20 is set in the steady state of light emission.

Here, the voltage between the gate and source terminals of the second transistor Tr2, represented by: Vgs=Vdata−VDDEL is substituted into the TFT saturation formula: Idrt=1/2Cox*μ*W/L*(Vgs-Vth)², the following equation is obtained:

$$Idrt ( = Ioled ) = 1 / 2 Cox * μ * W / L * {( Vdata - VDDEL - Vth )}^{2} .$$

According to the above, Idrt becomes a value that is dependent on the threshold voltage Vth of the second transistor Tr2 (that is, a current dependent on the threshold voltage Vth of the second transistor Tr2 flows to the display element 20), and it can be confirmed that the variation of the threshold voltage Vth affects Idrt.

In other words, the pixel circuit 210 (2Tr1C pixel circuit) shown in FIG. 19, unlike the pixel circuit 200 shown in FIG. 18, does not have the Vth correction function described above.

Note that according to FIGS. 21 and 22 described above, the pixel circuits 200 and 210 are driven by the gate signal Scan2 that is output (supplied) at the same timing from the shared gate signal lines. With this configuration, it can be said that even the combination of the pixel circuit 200 shown in FIG. 18 and the pixel circuit 210 shown in FIG. 19 can improve the light transmittance in the second display area DA2.

Although this embodiment is described on the assumption of such a case that a camera 100 (an image pickup element of the camera 100) is disposed on the rear surface of the display device DSP, this embodiment is applicable as well to the case where a sensor containing a light receiving element or the like that converts incident light into an electrical signal or a device equipped with such a sensor is placed on the rear surface of the display device DSP. In other words, the DSP of this embodiment need only be configured to improve the light transmittance in a predetermined area of the display area DA, and is not limited to those to be placed on the rear surface of the display device DSP.

All display devices, which are implementable with arbitrary changes in design by a person of ordinary skill in the art based on the display device described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A display device comprising:
a base;
a plurality of first pixels disposed in a first area included in a display area on the substrate; and
a plurality of second pixels disposed in a second area different from the first area, included in the display area on the substrate,
wherein
each of the plurality of first pixels includes a first pixel circuit including a plurality of transistors and a first display element driven by the first pixel circuit,
each of the plurality of second pixels includes a second pixel circuit including a plurality of transistors and a second display element driven by the second pixel circuit, and
the transistors in the second pixel circuit are less in number than the transistors in the first pixel circuit.

2. The display device of claim 1, wherein
the second area is located in a position overlapping a light receiving element that receives light via the display device.

3. The display device of claim 1, wherein
the first pixel circuit includes a transistor for realizing a function for correcting a variation in threshold voltage of a drive transistor which supplies a current to the first display element of the plurality of transistors in first pixel circuit, and
the second pixel circuit does not include a transistor for realizing a function for correcting a variation in threshold voltage of a drive transistor which supplies a current to the second display element of the plurality of transistors in second pixel circuit.

4. The display device of claim 1, wherein
part of a plurality of wiring lines connected to the first pixel circuit is connected to the second pixel circuit.

5. The display device of claim 1, wherein
an area of a region occupied by the second pixel circuit per unit area of the second area is smaller than an area of a region occupied by the first pixel circuit per unit area of the first area.

6. The display device of claim 1, further comprising:
a rib; and
a partition,
wherein
the first and second display elements each include a lower electrode, an organic layer, and an upper electrode,
the lower electrode is disposed on the base,
the rib includes an aperture overlapping the lower electrode;
the partition includes a lower portion disposed on the rib and an upper portion protruding from a side surface of the lower portion,
the organic layer is in contact with the lower electrode via the aperture, and
the upper electrode is disposed on the organic layer.

7. The display device of claim 6, further comprising:
a cap layer disposed on the upper electrode, and
a sealing layer disposed on the cap layer.

8. The display device of claim 7, wherein
the second area includes a region overlapping the aperture of the rib, where the second pixel circuit, the second display element, the cap layer and the sealing layer are not formed.

9. A display device comprising:
a base;
a plurality of first pixels disposed in a first area included in a display area on the base, and
a plurality of second pixels disposed in a second area different from the first area, included in the display area,
each of the plurality of first pixels includes a first display element and a first pixel circuit that drives the first display element,
each of the plurality of second pixels includes a second display element and a second pixel circuit that drives the second display element,
an area of a region occupied by the second pixel circuit per unit area of the second area is smaller than an area of a region occupied by the first pixel circuit per unit area of the first area.

10. The display device of claim 9, wherein
the second area is disposed in a position overlapping a light receiving element that receives light via the display device.

11. The display device of claim 9, wherein
the first pixel circuit includes a transistor for realizing a function of correcting a variation in threshold voltage of a drive transistor that supplies a current to the first display element of a plurality of transistors in the first pixel circuit, and
the second pixel circuit does not include a transistor for realizing a function of correcting a variation in threshold voltage of a drive transistor that supplies a current to the second display element of a plurality of transistors in the second pixel circuit.

12. The display device of claim 9, wherein
part of the plurality of wiring lines connected to the first pixel circuit is connected to the second pixel circuit.

13. The display device of claim 9, further comprising:
a rib; and
a partition,
wherein
the first and second display elements each include a lower electrode, an organic layer, and an upper electrode,
the lower electrode is disposed on the base,
the rib includes an aperture overlapping the lower electrode;
the partition includes a lower portion disposed on the rib and an upper portion protruding from a side surface of the lower portion,
the organic layer is in contact with the lower electrode via the aperture, and
the upper electrode is disposed on the organic layer.

14. The display device of claim 13, further comprising:
a cap layer disposed on the upper electrode, and
a sealing layer disposed on the cap layer.

15. The display device of claim 14, wherein
the second area includes a region overlapping the aperture of the rib, where the second pixel circuit, the second display element, the cap layer and the sealing layer are not formed.
